(19) United States
(12) Patent Application Publication
(10) Pub. No.: US 2025/0069863 A1
(43) Pub. Date: Feb. 27, 2025

(54) PLASMA PROCESSING APPARATUS

(71) Applicant: Tokyo Electron Limited, Tokyo (JP)

(72) Inventor: Chishio KOSHIMIZU, Kurokawa-gun (JP)

(73) Assignee: Tokyo Electron Limited, Tokyo (JP)

(21) Appl. No.: 18/939,729

(22) Filed: Nov. 7, 2024

Related U.S. Application Data
(63) Continuation of application No. PCT/JP2023/015235, filed on Apr. 14, 2023.

(30) Foreign Application Priority Data
May 19, 2022 (JP) 2022-082268

(51) Int. Cl. H01J 37/32

(52) U.S. Cl. CPC H01J 37/32715; H01J 37/32183; H01J 37/32568; H01J 2237/2007

(57) ABSTRACT

In the disclosed plasma processing apparatus, the substrate support includes a base and a dielectric portion on the base. The dielectric portion includes a first region configured to support a substrate placed thereon and a second region configured to support an edge ring placed thereon. First and second bias electrodes are disposed in the first and second regions, respectively. A shortest distance d_{W1} between a placement position of the substrate in the first region and the first bias electrode is not larger than a shortest distance d_{WE} between the first bias electrode and a placement position of the edge ring in the second region. A shortest distance d_{E1} between the second bias electrode and the placement position of the edge ring is not larger than a shortest distance d_{EW} between the second bias electrode and the placement position of the substrate.

### CROSS-REFERENCE TO RELATED APPLICATIONS

This application is a continuation application of PCT Application No. PCT/JP2023/015235, filed on Apr. 14, 2023, which claims the benefit of priority from Japanese Patent Application No. 2022-082268, filed on May 19, 2022. The entire contents of the above listed PCT and priority applications are incorporated herein by reference.

### BACKGROUND

### Field

The present disclosure relates to a plasma processing apparatus.

### Description of the Related Art

A plasma processing apparatus is used in plasma processing on a substrate. The plasma processing apparatus includes a chamber and a substrate support. The substrate support includes a base and an electrostatic chuck. The base comprises a lower electrode. A bias power source is connected to the base. The electrostatic chuck is disposed on the base. The electrostatic chuck includes an insulating layer and an electrode disposed in the insulating layer. A DC power source is connected to the electrode of the electrostatic chuck. Japanese Unexamined Patent Publication No. 2020-205444 discloses such a plasma processing apparatus.

### SUMMARY

In an example embodiment, A plasma processing apparatus is provided. The plasma processing apparatus includes a chamber, a substrate support, and at least one bias power source. The substrate support is disposed in in the chamber. The substrate support includes a base, a dielectric portion, a first bias electrode, and a second bias electrode. The dielectric portion is disposed on the base. The dielectric portion includes a first region configured to support a substrate placed thereon and a second region surrounding the first region and configured to support an edge ring placed thereon. The first bias electrode is disposed in the first region, and the second bias electrode is disposed in at least the second region. The at least one bias power source is configured to supply an electric bias for ion attraction to the first bias electrode and the second bias electrode. A shortest distance d_{W1} between a placement position of the substrate in the first region and the first bias electrode, a shortest distance d_{WE} between the first bias electrode and a placement position of the edge ring in the second region, a shortest distance d_{E1} between the second bias electrode and the placement position of the edge ring, and a shortest distance d_{EW} between the second bias electrode and the placement position of the substrate satisfy the following expressions (A) and (B).

$${d}_{W 1} \leq {d}_{W E} \qquad ( A )$$

$${d}_{E 1} \leq {d}_{E W} \qquad ( B )$$

The foregoing summary is illustrative only and is not intended to be in any way limiting. In addition to the illustrative aspects, example embodiments, and features described above, further aspects, example embodiments, and features will become apparent by reference to the drawings and the following detailed description.

### BRIEF DESCRIPTION OF THE DRAWINGS

FIG. 1 is a diagram for describing a configuration example of a plasma processing system.

FIG. 2 is a diagram for describing a configuration example of a capacitively coupled plasma processing apparatus.

FIG. 3 is a partially enlarged cross-sectional view of a substrate support as an example that may be adopted in the plasma processing apparatus according to an example embodiment.

FIG. 4 is a partially enlarged cross-sectional view of the substrate support as another example that may be adopted in the plasma processing apparatus according to the example embodiment.

FIG. 5 is a partially enlarged cross-sectional view of the substrate support as still another example that may be adopted in the plasma processing apparatus according to the example embodiment.

FIG. 6 is a partially enlarged cross-sectional view of the substrate support as still yet another example that may be adopted in the plasma processing apparatus according to the example embodiment.

FIG. 7 is a partially enlarged cross-sectional view of the substrate support as still yet another example that may be adopted in the plasma processing apparatus according to the example embodiment.

FIG. 8 is a partially enlarged cross-sectional view of the substrate support as still yet another example that may be adopted in the plasma processing apparatus according to the example embodiment.

FIG. 9 is a partially enlarged cross-sectional view of the substrate support as still yet another example that may be adopted in the plasma processing apparatus according to the example embodiment.

FIG. 10 is a partially enlarged cross-sectional view of the substrate support as still yet another example that may be adopted in the plasma processing apparatus according to the example embodiment.

### DETAILED DESCRIPTION

Hereinafter, various exemplary embodiments will be described in detail with reference to the drawings. In the drawings, the same or equivalent portions are denoted by the same reference symbols.

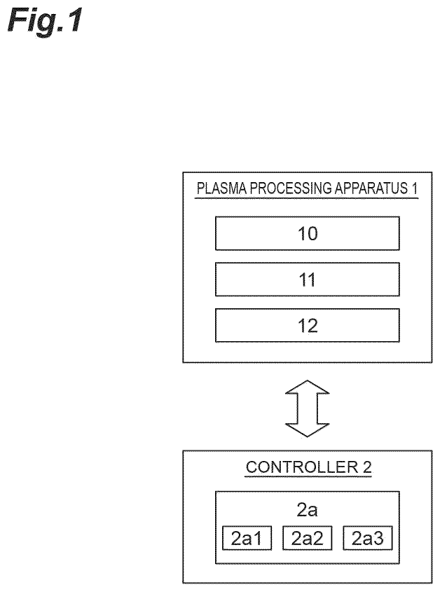

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), a surface wave plasma (SWP), or etc.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2al, a storage 2a2, and a communication interface 2a3. The controller 2 is implemented in, for example, a computer 2a. The processor 2al may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2al reads to execute the program from the storage 2a2. The medium may be of any type which can be accessed by the computer 2a or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

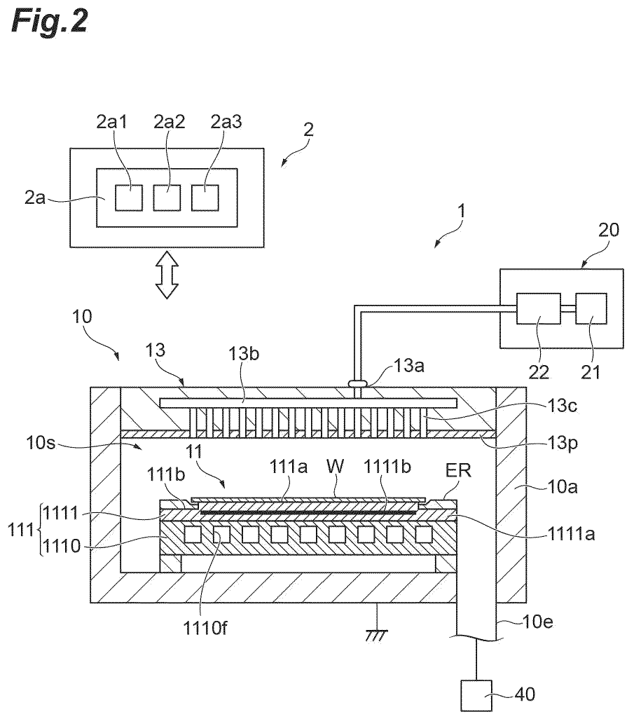

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The substrate support 11 are electrically insulated from the housing of the plasma processing chamber 10.

The substrate support 11 includes a body 111. The body 111 has a central region 111a for supporting a substrate W and an annular region 111b for supporting an edge ring ER. An example of the substrate W is a wafer. The annular region 111b of the body 111 surrounds the central region 111a of the body 111 in plan view. The substrate W is disposed on the central region 111a of the body 111, and the edge ring ER is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the edge ring ER.

In an embodiment, the body 111 includes a base 1110 and an electrostatic chuck 1111. The base 1110 includes a conductive member. The electrostatic chuck 1111 is disposed on the base 1110. The electrostatic chuck 1111 includes a dielectric portion 1111a and and an electrostatic electrode 1111b disposed in the dielectric portion 1111a.

The substrate support 11 may also include a temperature adjusting module that is configured to adjust at least one of the electrostatic chuck 1111, the edge ring ER, and the substrate to a target temperature. The temperature adjusting module may be a heater, a heat transfer medium, a flow passage 1110f, or any combination thereof. A heat transfer fluid, such as brine or gas, flows into the flow passage 1110f. In an embodiment, the flow passage 1110f is formed in the base 1110, one or more heaters are disposed in the dielectric portion 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

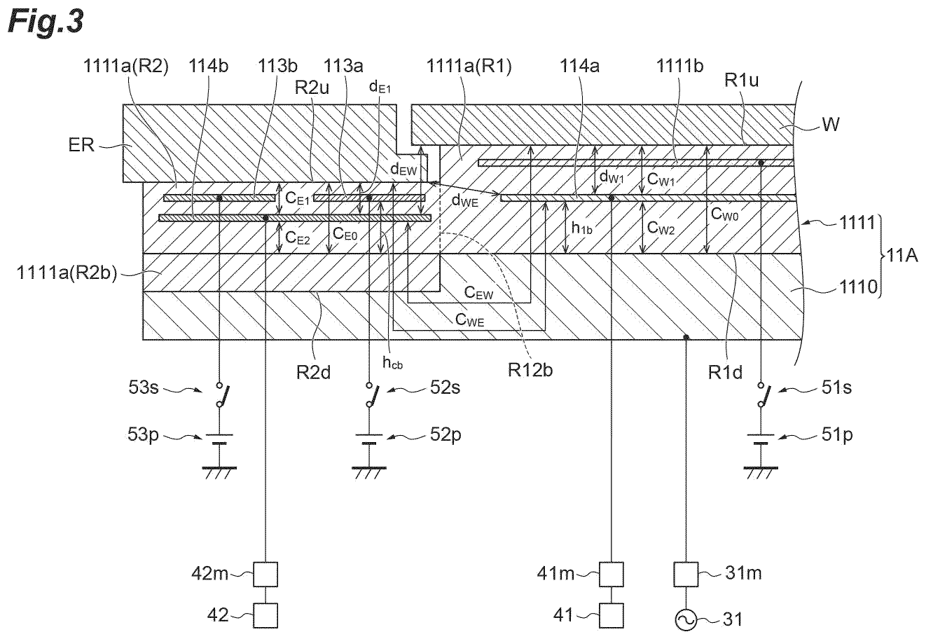

The description will be made below with reference to FIG. 3 together with FIGS. 1 and 2. FIG. 3 is a partially enlarged cross-sectional view of the substrate support as an example that may be adopted in the plasma processing apparatus according to the example embodiment. FIG. 3 illustrates a configuration example including a substrate support 11A and various power sources. The configuration example illustrated in FIG. 3 may be adopted in the plasma processing apparatus 1. In addition, the substrate support 11A may be adopted as the substrate support 11 of the plasma processing apparatus 1.

As illustrated in FIG. 3, the substrate support 11A includes a base 1110, a dielectric portion 1111a, a first bias electrode 114a, and a second bias electrode 114b. The base 1110 may have a substantially disc shape. The base 1110 may be formed of metal such as aluminum.

A radio frequency power source 31 is electrically coupled to the base 1110. The radio frequency power source 31 is configured to generate source radio frequency power for plasma generation in the chamber 10. Source radio frequency power has a source frequency. The source frequency may be a frequency within a range of 13 MHz to 100 MHz.

The radio frequency power source 31 is electrically connected to the base 1110 through a matcher 31m. The matcher 31m has a variable impedance. The variable impedance of the matcher 31m is set to reduce the reflection of the source radio frequency power from a load. The matcher 31m may be controlled by, for example, the controller 2.

The dielectric portion 1111a is disposed on the base 1110. The dielectric portion 1111a may have a substantially disc shape. The dielectric portion 1111a may be formed of ceramic such as aluminum oxide and aluminum nitride.

The dielectric portion 1111a includes a first region R1 and a second region R2. In FIG. 3, a boundary R12b between the first region R1 and the second region R2 is indicated by a broken line. The first region R1 and the second region R2 may be joined at the boundary R12b.

The first region R1 is configured to support the substrate W placed on an upper surface R1u thereof. The upper surface R1u is a placement position of the substrate W in the first region R1. The first region R1 is a region that includes the center of the dielectric portion 1111a in a radial direction and has a substantially circular shape in plan view. The above-described electrostatic electrode 1111b is disposed in the first region R1. A DC power source 51p is connected to the electrostatic electrode 1111b through a switch 51s. When a DC voltage from the DC power source 51p is applied to the electrostatic electrode 1111b, an electrostatic attraction force is generated between the first region R1 and the substrate W. The first region R1 holds the substrate W by the generated electrostatic attraction force.

The second region R2 surrounds the first region R1 on the radially outer side of the first region R1. The second region R2 is configured to support the edge ring ER placed on an upper surface R2u thereof. The upper surface R2u is a placement position of the edge ring ER in the second region R2. The second region R2 is a substantially annular region in plan view. In an embodiment, a position of the upper surface R2u of the second region R2 in a height direction may be lower than a position of the upper surface R1u of the first region R1 in the height direction. In addition, a position of a lower surface R2d of the second region R2 in the height direction may be lower than a position of a lower surface R1d of the first region R1 in the height direction. With such a configuration, it is possible to reduce or eliminate a difference between the thickness of the first region R1 and the thickness of the second region R2. A part R2b of the second region R2 may be integrated with the base 1110.

An electrostatic electrode 113a and an electrostatic electrode 113b may be disposed in the second region R2. The electrostatic electrode 113a and the electrostatic electrode 113b may extend in the circumferential direction with respect to the central axis of the dielectric portion 1111a. The electrostatic electrode 113b may be disposed on the radially outer side of the electrostatic electrode 113a. A DC power source 52p is connected to the electrostatic electrode 113a through a switch 52s. A DC power source 53p is connected to the electrostatic electrode 113b through a switch 53s. When a DC voltage from the DC power source 52p is applied to the electrostatic electrode 113a and a DC voltage from the DC power source 53p is applied to the electrostatic electrode 113b, an electrostatic attraction force is generated between the second region R2 and the edge ring ER. The second region R2 holds the edge ring ER by the generated electrostatic attraction force.

The first bias electrode 114a is provided in the first region R1. The first bias electrode 114a may be provided between the electrostatic electrode 1111b and the base 1110. A first bias power source 41 is electrically coupled to the first bias electrode 114a. The first bias power source 41 supplies an electric bias for ion attraction to the substrate W through the first bias electrode 114a.

A distance h1b in the height direction between the first bias electrode 114a and the lower surface R1d of the first region R1 may be equal to a distance hcb in the height direction between the electrostatic electrode 113a and the lower surface R1d of the first region R1. In addition, a distance h1b in the height direction between the first bias electrode 114a and the lower surface R1d of the first region R1 may be equal to a distance in the height direction between the electrostatic electrode 113b and the lower surface R1d of the first region R1. In this case, it is possible to form the first bias electrode 114a and the electrostatic electrode 113a and/or the electrostatic electrode 113b in the same layer when the electrostatic chuck 1111 is manufactured by stacking a plurality of dielectric sheets. Thus, the manufacturing of the electrostatic chuck 1111 is facilitated.

The second bias electrode 114b is disposed at least in the second region R2. In the embodiment of FIG. 3, the second bias electrode 114b is disposed only in the second region R2. The second bias electrode 114b may be disposed between each of the electrostatic electrodes 113a and 113b, and the base 1110. A second bias power source 42 is electrically coupled to the second bias electrode 114b. The second bias power source 42 supplies an electric bias for ion attraction to the edge ring ER through the second bias electrode 114b.

The electric bias generated by each of the first bias power source 41 and the second bias power source 42 has a waveform period or a wave form cycle. The waveform period of the electric bias is defined by a bias frequency. The bias frequency is, for example, a frequency of 100 kHz or more and 50 MHz or less. A time length of the waveform period of the electric bias is an inverse number of the bias frequency.

The electric bias generated by each of the first bias power source 41 and the second bias power source 42 may be bias radio frequency power. In this case, the first bias power source 41 is electrically connected to the first bias electrode 114a through a matcher 41m. The matcher 41m has a variable impedance. A variable impedance element or circuit of the matcher 41m is set to reduce the reflection of the bias radio frequency power from a load. In addition, the second bias power source 42 is electrically connected to the second bias electrode 114b through a matcher 42m. The matcher 42m has a variable impedance. A variable impedance element or circuit of the matcher 42m is set to reduce the reflection of the bias radio frequency power from a load. The matcher 41m and the matcher 42m may be controlled by, for example, the controller 2.

Alternatively, the electric bias generated by each of the first bias power source 41 and the second bias power source 42 may be a pulse of a voltage periodically generated. The pulse of the voltage may be a pulse of a negative voltage or a negative DC voltage. The pulse of the voltage may have a positive potential or a positive and negative potential. In addition, the pulse of the voltage may have a level that changes between two potentials. When the electric bias is a pulse of a voltage, the matcher 41m and the matcher 42m do not need to be provided.

The substrate support 11A may satisfy the following expressions (A) and (B). That is, the shortest distance d_{W1} between the placement position (that is, the upper surface R1u) of the substrate W in the first region R1 and the first bias electrode 114a and the shortest distance d_{WE} between the first bias electrode 114a and the placement position (that is, the upper surface R2u) of the edge ring ER in the second region R2 may satisfy the following expression (A). In addition, the shortest distance d_{E1} between the second bias electrode 114b and the placement position (that is, the upper surface R2u) of the edge ring ER and the shortest distance d_{EW} between the second bias electrode 114b and the placement position (that is, the upper surface R1U) of the substrate W may satisfy the following expression (B).

$${d}_{W 1} \leq {d}_{W E} \qquad ( A )$$

$${d}_{E 1} \leq {d}_{E W} \qquad ( B )$$

The shortest distance d_{W1} may be longer than the shortest distance d_{E1}. In addition, the shortest distance d_{WE} may be longer than the shortest distance d_{EW}.

When the expression (A) is satisfied, the substrate support 11A can suppress the distribution of the electric bias supplied to the first bias electrode 114a to the edge ring ER. In addition, when the expression (B) is satisfied, the substrate support 11A can suppress the distribution of the electric bias supplied to the second bias electrode 114b to the substrate W. Thus, in the substrate support 11A, when the expressions (A) and (B) are satisfied, the performance of independently supplying the electric bias to the substrate W and the edge ring ER is improved.

The substrate support 11A may satisfy the following expressions (1) to (3) in addition to or instead of the expressions (A) and (B).

$$0.5 \times {C}_{W 0} / {S}_{W} < {C}_{E 0} / {S}_{E} < 1.5 \times {C}_{W 0} / {S}_{W} \qquad ( 1 )$$

$${C}_{W 1} \geq {C}_{WE} \qquad ( 2 )$$

$${C}_{E 1} \geq {C}_{EW} \qquad ( 3 )$$

C_{W0} is an electrostatic capacitance between the substrate W and the base 1110. S_{W} is an area of the surface (front surface or back surface) of the substrate W. C_{E0} is an electrostatic capacitance between the base 1110 and the edge ring ER. S_{E} is an area of the surface (front surface or back surface) of the edge ring ER. C_{W1} is an electrostatic capacitance between the substrate W and the first bias electrode 114a. C_{WE} is an electrostatic capacitance between the first bias electrode 114a and the edge ring ER. C_{E1} is an electrostatic capacitance between the second bias electrode 114b and the edge ring ER. C_{EW} is an electrostatic capacitance between the second bias electrode 114b and the substrate W. Each of the electrostatic capacitance C_{WE} and the electrostatic capacitance C_{EW} may be 10 (nF) or less or 3 (nF) or less.

In the substrate support 11A, the electrostatic capacitance C_{WE}, the electrostatic capacitance C_{E0}, and the electrostatic capacitance C_{W2} between the first bias electrode 114a and the base 1110 satisfy C_{WE}=C_{W2}× C_{E0}/(C_{W2}+C_{E0}). In addition, the electrostatic capacitance C_{EW}, the electrostatic capacitance C_{W0}, and the electrostatic capacitance C_{E2} between the second bias electrode 114b and the base 1110 satisfy C_{EW}=C_{W0}×C_{E2}/(C_{W0}+C_{E2}).

Since the substrate support 11A satisfies the expression (1), a difference between source radio frequency power per unit area coupled to plasma from the substrate W and source radio frequency power per unit area coupled to plasma from the edge ring ER is reduced. In addition, since the substrate support 11A satisfies the expression (2), it is possible to suppress the distribution of the electric bias supplied to the first bias electrode 114a to the edge ring ER. In addition, since the substrate support 11A satisfies the expression (3), it is possible to suppress the distribution of the electric bias supplied to the second bias electrode 114b to the substrate W. Thus, the performance of independently supplying the electric bias to the substrate W and the edge ring ER is improved.

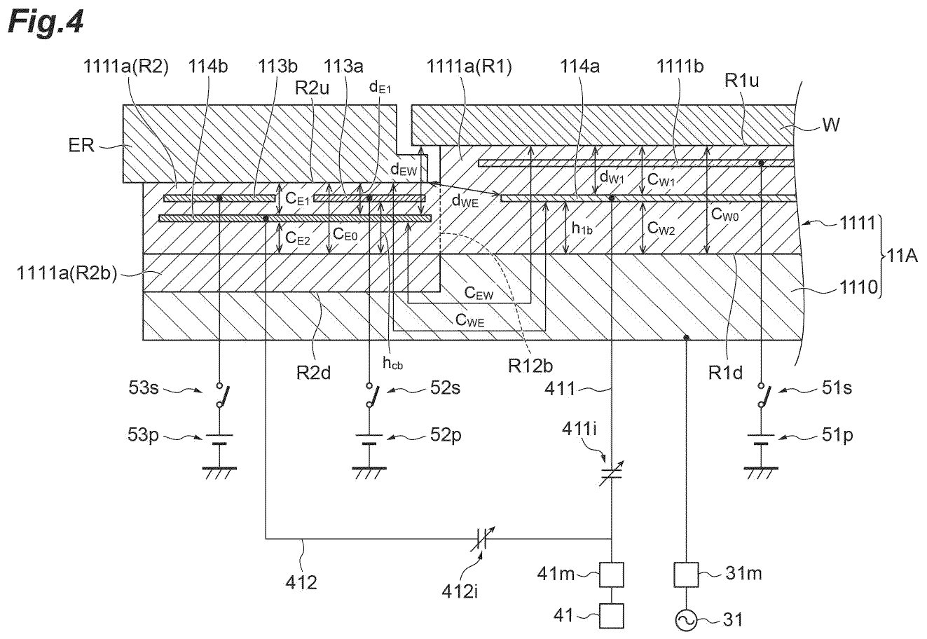

The description will be made below with reference to FIG. 4. FIG. 4 is a partially enlarged cross-sectional view of the substrate support as another example that may be adopted in the plasma processing apparatus according to the example embodiment. FIG. 4 illustrates a configuration example including the above-described substrate support 11A and various power sources. The configuration example illustrated in FIG. 4 may be adopted in the plasma processing apparatus 1.

The plasma processing apparatus 1 adopting the configuration example illustrated in FIG. 4 does not include the second bias power source 42. In the configuration example illustrated in FIG. 4, the first bias power source 41 is electrically coupled to the first bias electrode 114a through an electrical path 411. In addition, the first bias power source 41 is electrically coupled to the second bias electrode 114b through an electrical path 412.

The electrical path 411 includes a variable impedance element 411i. The electrical path 412 includes a variable impedance element 412i. Each of the variable impedance element 411i and the variable impedance element 412i may be a variable capacitor, or may be another variable impedance element. A distribution ratio of the electric bias to each of the first bias electrode 114a and the second bias electrode 114b is adjusted by setting the variable impedance of each of the variable impedance element 411i and the variable impedance element 412i. In the configuration example illustrated in FIG. 4, one of the variable impedance element 411i or the variable impedance element 412i may be omitted.

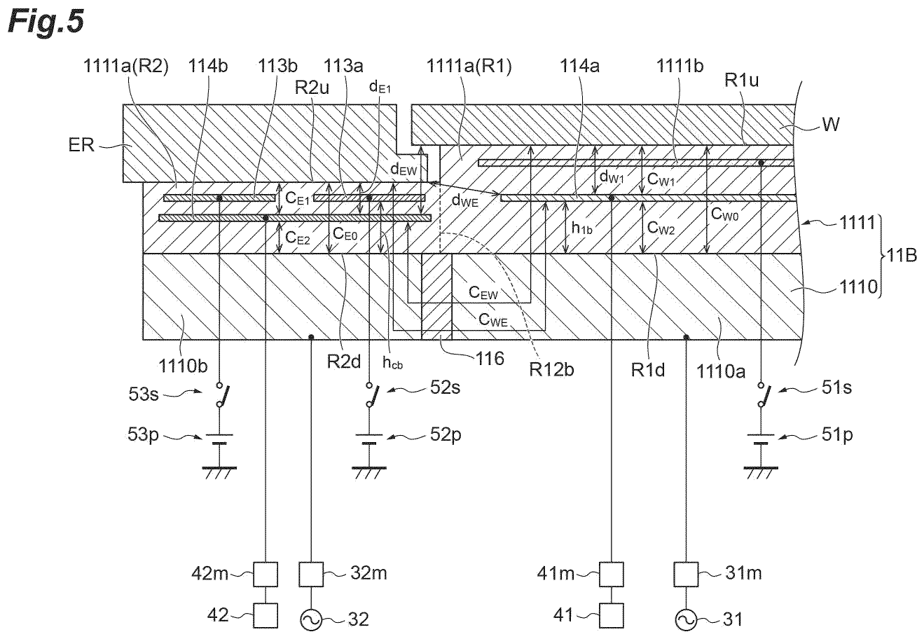

The description will be made below with reference to FIG. 5. FIG. 5 is a partially enlarged cross-sectional view of the substrate support as still another example that may be adopted in the plasma processing apparatus according to the example embodiment. FIG. 5 illustrates a configuration example including a substrate support 11B and various power sources. The configuration example illustrated in FIG. 5 may be adopted in the plasma processing apparatus 1. In addition, the substrate support 11B may be adopted as the substrate support 11 of the plasma processing apparatus 1. The configuration example illustrated in FIG. 5 will be described below from the viewpoint of differences from the configuration example illustrated in FIG. 3.

In the substrate support 11B, a base 1110 includes a first base 1110a and a second base 1110b. The first base 1110a has a substantially disc shape and is provided below the first region R1. The second base 1110b has a substantially annular shape in plan view, and is provided below the second region R2. The first base 1110a and the second base 1110b are separated from each other by a dielectric portion 116 provided therebetween. The dielectric portion 116 is formed of a dielectric.

In the configuration example illustrated in FIG. 5, a radio frequency power source 31 is electrically connected to the first base 1110a through the matcher 31m. In addition, a radio frequency power source 32 is electrically connected to the second base 1110b through a matcher 32m. The radio frequency power source 32 generates source radio frequency power for plasma generation, as with the radio frequency power source 31. The matcher 32m has a variable impedance. The variable impedance of the matcher 32m is set to reduce the reflection of the source radio frequency power generated by the radio frequency power source 32, from the load. Other configurations in the configuration example illustrated in FIG. 5 are same as the corresponding configurations of the configuration example illustrated in FIG. 3.

The substrate support 11B may also satisfy the above-described expressions (A) and (B). The substrate support 11B may satisfy the above-described expressions (1) to (3) in addition to or instead of the expressions (A) and (B). Each of the electrostatic capacitance C_{WE} and the electrostatic capacitance C_{EW} may be 10 (nF) or less or 3 (nF) or less. In the substrate support 11B, the electrostatic capacitance C_{WE}, the electrostatic capacitance C_{E0}, the electrostatic capacitance C_{W2}, and the electrostatic capacitance C_{B} between the first base 1110a and the second base 1110b satisfy C_{WE}=C_{W2}× C_{B}×C_{E0}/(C_{W2}× C_{B}+C_{B}×C_{E0}+C_{E0}×C_{W2}). The electrostatic capacitance C_{B} is an electrostatic capacitance of the dielectric portion 116. In addition, the electrostatic capacitance C_{EW}, the electrostatic capacitance C_{W0}, the electrostatic capacitance C_{E2}, and the electrostatic capacitance C_{B} satisfy C_{EW}=C_{W0}×C_{B}×C_{E2}/(C_{W0}×C_{B}+C×C_{E2}+C_{E2}× C_{W0}).

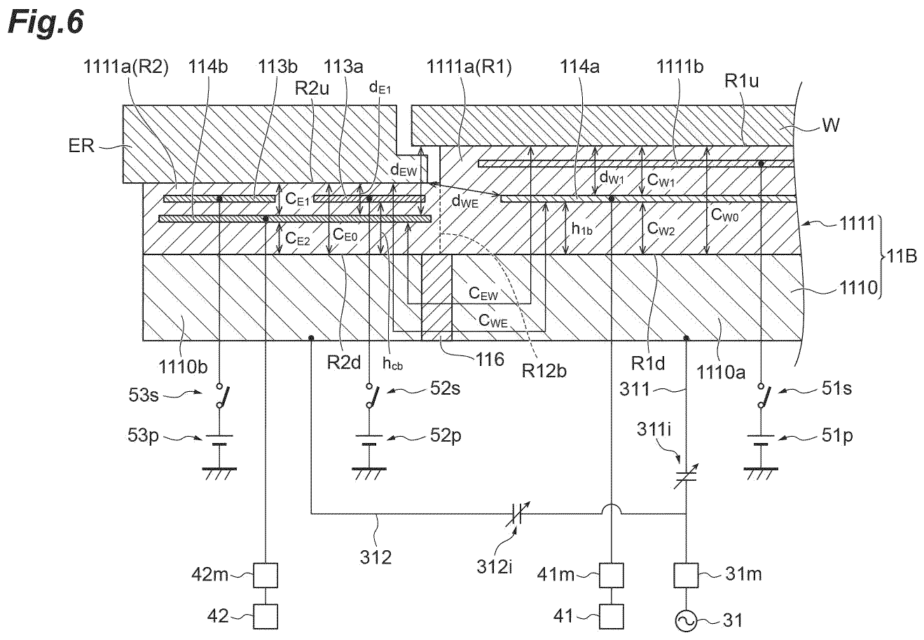

The description will be made below with reference to FIG. 6. FIG. 6 is a partially enlarged cross-sectional view of the substrate support as still yet another example that may be adopted in the plasma processing apparatus according to the example embodiment. FIG. 6 illustrates a configuration example including the above-described substrate support 11B and various power sources. The configuration example illustrated in FIG. 6 may be adopted in the plasma processing apparatus 1.

In the configuration example illustrated in FIG. 6, the radio frequency power source 31 is electrically coupled to the first base 1110a through an electrical path 311. In addition, the radio frequency power source 31 is electrically coupled to the second base 1110b through an electrical path 312.

The electrical path 311 includes a variable impedance element 311i. The electrical path 312 includes a variable impedance element 312i. Each of the variable impedance element 311i and the variable impedance element 312i may be a variable capacitor, or may be another variable impedance element. A distribution ratio of the source radio frequency power generated by the radio frequency power source 31 to each of the first base 1110a and the second base 1110b is adjusted by setting the variable impedance of each of the variable impedance element 311i and the variable impedance element 312i. In the configuration example illustrated in FIG. 6, one of the variable impedance element 311i or the variable impedance element 312i may be omitted.

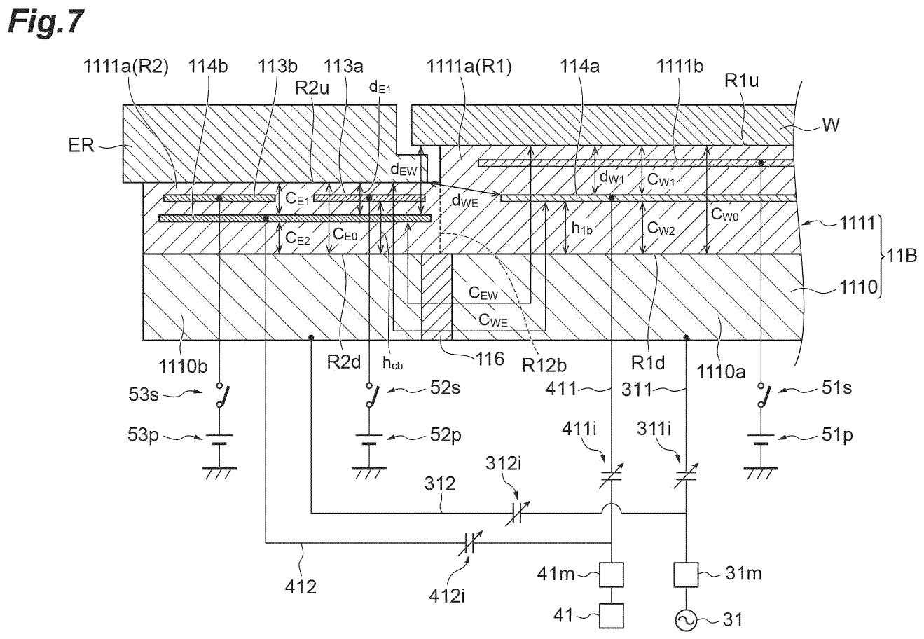

The description will be made below with reference to FIG. 7. FIG. 7 is a partially enlarged cross-sectional view of the substrate support as still yet another example that may be adopted in the plasma processing apparatus according to the example embodiment. FIG. 7 illustrates a configuration example including the above-described substrate support 11B and various power sources. The configuration example illustrated in FIG. 7 may be adopted in the plasma processing apparatus 1. The configuration example illustrated in FIG. 7 will be described below from the viewpoint of differences from the configuration example illustrated in FIG. 6.

The plasma processing apparatus 1 adopting the configuration example illustrated in FIG. 7 does not include the second bias power source 42. In the configuration example illustrated in FIG. 7, the first bias power source 41 is electrically coupled to the first bias electrode 114a through the electrical path 411. In addition, the first bias power source 41 is electrically coupled to the second bias electrode 114b through an electrical path 412.

The electrical path 411 includes a variable impedance element 411i. The electrical path 412 includes a variable impedance element 412i. Each of the variable impedance element 411i and the variable impedance element 412i may be a variable capacitor, or may be another variable impedance element. A distribution ratio of the electric bias to each of the first bias electrode 114a and the second bias electrode 114b is adjusted by setting the variable impedance of each of the variable impedance element 411i and the variable impedance element 412i. In the configuration example illustrated in FIG. 7, one of the variable impedance element 411i or the variable impedance element 412i may be omitted.

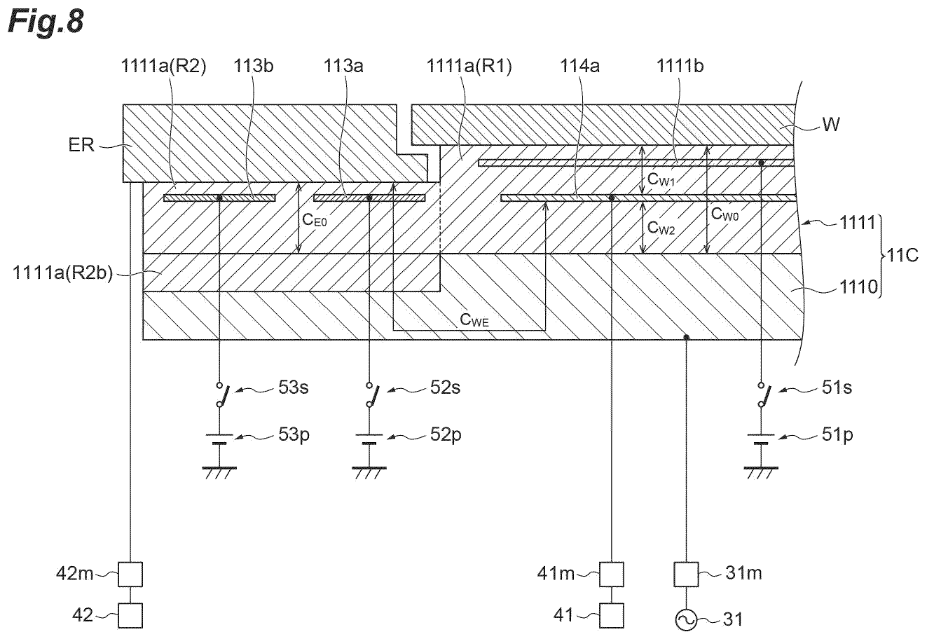

The description will be made below with reference to FIG. 8. FIG. 8 is a partially enlarged cross-sectional view of the substrate support as still yet another example that may be adopted in the plasma processing apparatus according to the example embodiment. FIG. 8 illustrates a configuration example including a substrate support 11C and various power sources. The configuration example illustrated in FIG. 8 may be adopted in the plasma processing apparatus 1. In addition, the substrate support 11C may be adopted as the substrate support 11 of the plasma processing apparatus 1. The configuration example illustrated in FIG. 8 will be described below from the viewpoint of differences from the configuration example illustrated in FIG. 3.

As illustrated in FIG. 8, the substrate support 11C does not include the second bias electrode 114b. The second bias power source 42 is electrically connected to the edge ring ER. The substrate support 11C satisfies the following expressions (4) and (5).

$$0.5 \times {C}_{W 0} / {S}_{W} < {C}_{E 0} / {S}_{E} < 1.5 \times {C}_{W 0} / {S}_{W} \qquad ( 4 )$$

$${C}_{W 1} \geq {C}_{W E} = {C}_{W 2} \times {C}_{E 0} / ( {C}_{W 2} + {C}_{E 0} ) \qquad ( 5 )$$

C_{W0} is an electrostatic capacitance between the substrate W and the base 1110. S_{W} is an area of the back surface of the substrate W. C_{E0} is an electrostatic capacitance between the base 1110 and the edge ring ER. S_{E}H is an area of the back surface of the edge ring ER. C_{W1} is an electrostatic capacitance between the substrate W and the first bias electrode 114a. C_{WE} is an electrostatic capacitance between the first bias electrode 114a and the edge ring ER. C_{W2} is an electrostatic capacitance between the first bias electrode 114a and the base 1110. The electrostatic capacitance C_{WE} may be 10 (nF) or 3 (nF) or less.

Since the substrate support 11C satisfies the expression (4), a difference between source radio frequency power per unit area coupled to plasma from the substrate W and source radio frequency power per unit area coupled to plasma from the edge ring ER is reduced. In addition, since the substrate support 11C satisfies the expression (5), it is possible to suppress the distribution of the electric bias supplied to the first bias electrode 114a to the edge ring ER. Thus, the performance of independently supplying the electric bias to one of the substrate W and the edge ring ER is improved.

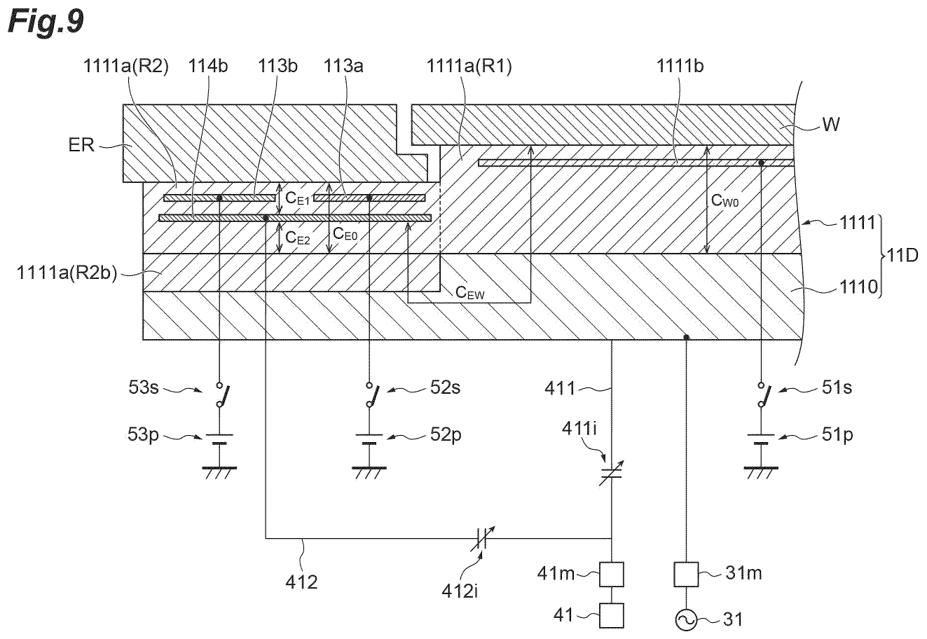

The description will be made below with reference to FIG. 9. FIG. 9 is a partially enlarged cross-sectional view of the substrate support as still yet another example that may be adopted in the plasma processing apparatus according to the example embodiment. FIG. 9 illustrates a configuration example including a substrate support 11D and various power sources. The configuration example illustrated in FIG. 9 may be adopted in the plasma processing apparatus 1. In addition, the substrate support 11D may be adopted as the substrate support 11 of the plasma processing apparatus 1. The configuration example illustrated in FIG. 9 will be described below from the viewpoint of differences from the configuration example illustrated in FIG. 3.

As illustrated in FIG. 9, the substrate support 11D does not include the first bias electrode 114a. In addition, in the configuration example illustrated in FIG. 9, the plasma processing apparatus 1 does not include the second bias power source 42. In the configuration example illustrated in FIG. 9, the first bias power source 41 is electrically coupled to the base 1110 through the electrical path 411. In addition, the first bias power source 41 is electrically coupled to the second bias electrode 114b through an electrical path 412.

The electrical path 411 includes a variable impedance element 411i. The electrical path 412 includes a variable impedance element 412i. Each of the variable impedance element 411i and the variable impedance element 412i may be a variable capacitor, or may be another variable impedance element. A distribution ratio of the electric bias to each of the first bias electrode 114a and the second bias electrode 114b is adjusted by setting the variable impedance of each of the variable impedance element 411i and the variable impedance element 412i. In the configuration example illustrated in FIG. 9, one of the variable impedance element 411i or the variable impedance element 412i may be omitted.

The substrate support 11D satisfies the following expressions (6) and (7).

$$0.5 \times {C}_{W 0} / {S}_{W} < {C}_{E 0} / {S}_{E} < 1.5 \times {C}_{W 0} / {S}_{W} \qquad ( 6 )$$

$${C}_{E 1} \geq {C}_{E W} = {C}_{W 0} \times {C}_{E 2} / ( {C}_{W 0} + {C}_{E 2} ) \qquad ( 7 )$$

C_{W0} is an electrostatic capacitance between the substrate W and the base 1110. S_{W} is an area of the back surface of the substrate W. C_{E0} is an electrostatic capacitance between the base 1110 and the edge ring ER. S_{E} is an area of the back surface of the edge ring ER. C_{E1} is an electrostatic capacitance between the second bias electrode 114b and the edge ring ER. C_{EW} is an electrostatic capacitance between the second bias electrode 114b and the substrate W. C_{E2} is an electrostatic capacitance between the second bias electrode 114b and the base 1110. The electrostatic capacitance C_{EW} may be 10 (nF) or 3 (nF) or less.

Since the substrate support 11D satisfies the expression (6), a difference between source radio frequency power per unit area coupled to plasma from the substrate W and source radio frequency power per unit area coupled to plasma from the edge ring ER is reduced. In addition, since the substrate support 11D satisfies the expression (7), it is possible to suppress the distribution of the electric bias supplied to the second bias electrode 114b to the substrate W. Thus, the performance of independently supplying the electric bias to one of the substrate W and the edge ring ER is improved.

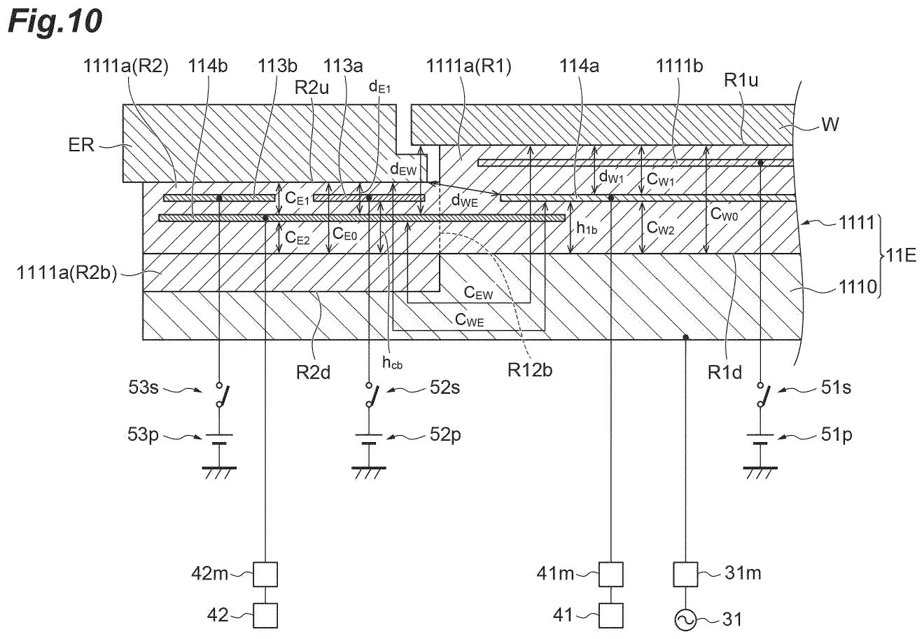

The description will be made below with reference to FIG. 10. FIG. 10 is a partially enlarged cross-sectional view of the substrate support as still yet another example that may be adopted in the plasma processing apparatus according to the example embodiment. FIG. 10 illustrates a configuration example including a substrate support 11E and various power sources. The configuration example illustrated in FIG. 10 may be adopted in the plasma processing apparatus 1. In addition, the substrate support 11E may be adopted as the substrate support 11 of the plasma processing apparatus 1. The configuration example illustrated in FIG. 10 will be described below from the viewpoint of differences from the configuration example illustrated in FIG. 3.

In the substrate support 11E, the second bias electrode 114b is provided in the second region R2 and is also partially disposed in the first region R1. That is, the second bias electrode 114b extends from the second region R2 into the first region R1. A part of the second bias electrode 114b extends to overlap with the first bias electrode 114a in the first region R1 when viewed in the vertical direction (that is, in plan view). Other configurations in the configuration example illustrated in FIG. 10 are same as the corresponding configurations of the configuration example illustrated in FIG. 3. With the substrate support 11E, the electrostatic capacitance Cw and the electrostatic capacitance C_{EW} can be adjusted by adjusting the area in which the first bias electrode 114a and the second bias electrode 114b overlap with each other in the first region R1. The configuration in which the first bias electrode 114a and the second bias electrode 114b overlap with each other in the first region R1 may also be adopted in the configuration examples of FIGS. 4 to 7.

While various example embodiments have been described above, various additions, omissions, substitutions and changes may be made without being limited to the exemplary embodiments described above. Elements of the different embodiments may be combined to form another embodiment.

For example, the substrate support does not need to include the first bias electrode 114a, and the electrostatic electrode 1111b may also serve as the first bias electrode 114a. In addition, the substrate support does not need to include the second bias electrode 114b, and the electrostatic electrode 113a and the electrostatic electrode 113b may also serve as the second bias electrode 114b.

Here, various example embodiments included in the present disclosure will be described in [E1] to [E16] and [G1] to [G14] below.

[E1]

A plasma processing apparatus including:
a chamber;
a substrate support disposed in the chamber, the substrate support including a base, a dielectric portion disposed on the base, a first bias electrode, and a second bias electrode, the dielectric portion including a first region configured to support a substrate placed thereon and a second region surrounding the first region and configured to support an edge ring placed thereon, the first bias electrode being disposed in the first region, and the second bias electrode being disposed in at least the second region; and
at least one bias power source configured to supply an electric bias for ion attraction to the first bias electrode and the second bias electrode,
wherein a shortest distance d_{W1} between a placement position of the substrate in the first region and the first bias electrode, a shortest distance d_{WE} between the first bias electrode and a placement position of the edge ring in the second region, a shortest distance d_{E1} between the second bias electrode and the placement position of the edge ring, and a shortest distance d_{EW} between the second bias electrode and the placement position of the substrate satisfy the following expressions (A) and (B).

$${d}_{W 1} \leq {d}_{W E} \qquad ( A )$$

$${d}_{E 1} \leq {d}_{E W} \qquad ( B )$$

[E2]

The plasma processing apparatus according to E1,
wherein the plasma processing apparatus includes a first bias power source electrically coupled to the first bias electrode and a second bias power source electrically coupled to the second bias electrode, as the at least one bias power source.

[E3]

The plasma processing apparatus according to E1,
wherein the plasma processing apparatus includes a single bias power source electrically coupled to the first bias electrode through a first electrical path and electrically coupled to the second bias electrode through a second electrical path, as the at least one bias power source, and
at least one of the first electrical path and the second electrical path includes a variable impedance element.

[E4]

The plasma processing apparatus according to E1,
wherein the base includes a first base disposed below the first region and a second base disposed below the second region, and
the first base and the second base are separated from each other by an other dielectric portion disposed between the first base and the second base.

[E5]

The plasma processing apparatus according to E4,
wherein the plasma processing apparatus includes a first bias power source electrically coupled to the first bias electrode and a second bias power source electrically coupled to the second bias electrode, as the at least one bias power source.

[E6]

The plasma processing apparatus according to E5, further including a first radio frequency power source electrically coupled to the first base and a second radio frequency power source electrically coupled to the second base, as at least one radio frequency power source configured to generate source radio frequency power for plasma generation.

[E7]

The plasma processing apparatus according to E4 or E5, further including a single radio frequency power source electrically connected to the first base through a first electrical path and electrically coupled to the second base through a second electrical path, as at least one radio frequency power source configured to generate source radio frequency power for plasma generation,
wherein at least one of the first electrical path and the second electrical path includes a variable impedance element.

[E8]

The plasma processing apparatus according to E4,
wherein the plasma processing apparatus includes a single bias power source electrically coupled to the first bias electrode through a first electrical path and electrically coupled to the second bias electrode through a second electrical path, as the at least one bias power source,
at least one of the first electrical path and the second electrical path includes a variable impedance element,
the plasma processing apparatus further includes a single radio frequency power source electrically connected to the first base through a third electrical path and electrically coupled to the second base through a fourth electrical path, as at least one radio frequency power source configured to generate source radio frequency power for plasma generation, and
at least one of the third electrical path and the fourth electrical path includes a variable impedance element.

[E9]

The plasma processing apparatus according to any one of E1 to E8,
wherein a part of the second bias electrode is disposed to overlap the first bias electrode as viewed in a vertical direction in the first region.

[E10]

The plasma processing apparatus according to any one of E1 to E9,
wherein the electric bias is bias radio frequency power or a pulse of a voltage periodically generated.

[E11]

The plasma processing apparatus according to any one of E1 to E10,
wherein a position of an upper surface of the second region in a height direction is lower than a position of an upper surface of the first region in the height direction, and
a position of a lower surface of the second region in the height direction is lower than a position of a lower surface of the first region in the height direction.

[E12]

The plasma processing apparatus according to any one of E1 to E11,
wherein a part of the second region is integrated with the base.

[E13]

The plasma processing apparatus according to any one of E1 to E12,
wherein the first region and the second region are joined at a boundary between the first region and the second region.

[E14]

The plasma processing apparatus according to any one of E1 to E13,
wherein the substrate support further includes an electrostatic electrode disposed in the second region, and
a distance between the first bias electrode and a lower surface of the first region in a height direction is equal to a distance between the electrostatic electrode and the lower surface of the first region in the height direction.

[E15]

The plasma processing apparatus according to any one of E1 to E14,
wherein the shortest distance d_{W1} is longer than the shortest distance d_{E1}.

[E16]

The plasma processing apparatus according to claim 1,
wherein the shortest distance d_{WE} is longer than the shortest distance d_{EW}.

[G1]

A plasma processing apparatus including:
a chamber;
a substrate support disposed in the chamber, the substrate support including a base, a dielectric portion disposed on the base, a first bias electrode, and a second bias electrode, the dielectric portion including a first region configured to support a substrate placed thereon and a second region surrounding the first region and configured to support an edge ring placed thereon, the first bias electrode being disposed in the first region, and the second bias electrode being disposed in at least the second region;
at least one radio frequency power source electrically coupled to the base and configured to generate source radio frequency power for plasma generation; and
at least one bias power source configured to supply an electric bias for ion attraction to the first bias electrode and the second bias electrode,
wherein an electrostatic capacitance C_{W0} between the substrate and the base, an area S_{W} of a back surface of the substrate, an electrostatic capacitance C_{E0} between the base and the edge ring, an area S_{E} of a back surface of the edge ring, an electrostatic capacitance C_{W1} between the substrate and the first bias electrode, an electrostatic capacitance C_{WE} between the first bias electrode and the edge ring, an electrostatic capacitance C_{E1} between the second bias electrode and the edge ring, and an electrostatic capacitance C_{EW} between the second bias electrode and the substrate satisfy the following expressions (1) to (3).

$$0.5 \times {C}_{W 0} / {S}_{W} < {C}_{E 0} / {S}_{E} < 1.5 \times {C}_{W 0} / {S}_{W} \qquad ( 1 )$$

$${C}_{W 1} \geq {C}_{WE} \qquad ( 2 )$$

$${C}_{E 1} \geq {C}_{EW} \qquad ( 3 )$$

In the embodiment of G1, a difference between source radio frequency power per unit area coupled to plasma from the substrate and source radio frequency power per unit area coupled to plasma from the edge ring is reduced. In addition, in the embodiment of G1, it is possible to suppress the distribution of the electric bias supplied to the first bias electrode to the edge ring. In addition, in the embodiment of G1, it is possible to suppress the distribution of the electric bias supplied to the second bias electrode to the substrate. Thus, according to the embodiment of G1, the performance of independently supplying the electric bias to the substrate and the edge ring is improved. Each of the electrostatic capacitance C_{WE} and the electrostatic capacitance C_{EW} may be 10 (nF) or less.

[G2]

The plasma processing apparatus according to G1,
wherein the plasma processing apparatus includes a first bias power source electrically coupled to the first bias electrode and a second bias power source electrically coupled to the second bias electrode, as the at least one bias power source.

[G3]

The plasma processing apparatus according to G1,
wherein the plasma processing apparatus includes a single bias power source electrically coupled to the first bias electrode through a first electrical path and electrically coupled to the second bias electrode through a second electrical path, as the at least one bias power source, and
at least one of the first electrical path and the second electrical path includes a variable impedance element.

[G4]

The plasma processing apparatus according to G2 or G3, wherein
the electrostatic capacitance C_{WE}, the electrostatic capacitance C_{E0}, and an electrostatic capacitance C_{W2} between the first bias electrode and the base satisfy C_{WE}=C_{W2}×C_{E0}/(C_{W2}+C_{E0}), and
the electrostatic capacitance C_{EW}, the electrostatic capacitance C_{W0}, and an electrostatic capacitance C_{E2} between the second bias electrode and the base satisfy C_{EW}=C_{W0}×C_{E2}/(C_{W0}+C_{E2}).

[G5]

The plasma processing apparatus according to G1,
wherein the base includes a first base disposed below the first region and a second base disposed below the second region, and
the first base and the second base are separated from each other by an other dielectric portion disposed between the first base and the second base.

[G6]

The plasma processing apparatus according to G5,
wherein the plasma processing apparatus includes a first bias power source electrically coupled to the first bias electrode and a second bias power source electrically coupled to the second bias electrode, as the at least one bias power source.

[G7]

The plasma processing apparatus according to G6,
wherein the plasma processing apparatus includes a first radio frequency power source electrically coupled to the first base and a second radio frequency power source electrically coupled to the second base, as the at least one radio frequency power source.

[G8]

The plasma processing apparatus according to G5,
wherein the plasma processing apparatus includes a single bias power source electrically coupled to the first bias electrode through a first electrical path and electrically coupled to the second bias electrode through a second electrical path, as the at least one bias power source, and
at least one of the first electrical path and the second electrical path includes a variable impedance element. [G9]

The plasma processing apparatus according to G5,
wherein the plasma processing apparatus includes a single bias power source electrically coupled to the first bias electrode through a first electrical path and electrically coupled to the second bias electrode through a second electrical path, as the at least one bias power source,
at least one of the first electrical path and the second electrical path includes a variable impedance element,
the plasma processing apparatus includes a single radio frequency power source electrically connected to the first base through a third electrical path and electrically coupled to the second base through a fourth electrical path, as the at least one radio frequency power source, and
at least one of the third electrical path and the fourth electrical path includes a variable impedance element.

[G10]

The plasma processing apparatus according to any one of G5 to G9, wherein
the electrostatic capacitance C_{WE}, the electrostatic capacitance C_{E0}, an electrostatic capacitance C_{W2} between the first bias electrode and the base, and an electrostatic capacitance C_{B} between the first base and the second base satisfy C_{WE}=C_{W2}× C_{B}×C_{E0}/(C_{W2}× C_{B}+C_{B}×C_{E0}+C_{E0}× C_{W2}), and
the electrostatic capacitance C_{EW}, the electrostatic capacitance C_{W0}, an electrostatic capacitance C_{E2} between the second bias electrode and the base, and the electrostatic capacitance C_{B} satisfy C_{EW}=C_{W0}×C_{B}×C_{E2}/(C_{W0}×C_{B}+C×C_{E2}+C_{E2}× C_{W0}).

[G11]

The plasma processing apparatus according to any one of G1 to G10,
wherein a part of the second bias electrode is disposed to overlap the first bias electrode as viewed in a vertical direction in the first region.

[G12]

A plasma processing apparatus including:
a chamber;
a substrate support disposed in the chamber, the substrate support including a base, a dielectric portion disposed on the base, and a bias electrode, the dielectric portion including a first region configured to support a substrate placed thereon and a second region surrounding the first region and configured to support an edge ring placed thereon, and the bias electrode being disposed in the first region;
a radio frequency power source electrically coupled to the base and configured to generate source radio frequency power for plasma generation;
a first bias power source electrically coupled to the bias electrode configured to supply an electric bias for ion attraction to the bias electrode; and
a second bias power source electrically coupled to the edge ring and configured to supply an electric bias for ion attraction to the edge ring,
wherein an electrostatic capacitance C_{W0} between the substrate and the base, an area S_{W} of a back surface of the substrate, an electrostatic capacitance C_{E0} between the base and the edge ring, an area S_{E} of a back surface of the edge ring, an electrostatic capacitance C_{W1} between the substrate and the bias electrode, an electrostatic capacitance C_{WE} between the bias electrode and the edge ring, and an electrostatic capacitance C_{W2} between the bias electrode and the base satisfy the following expressions (4) and (5).

$$0.5 \times {C}_{W 0} / {S}_{W} < {C}_{E 0} / {S}_{E} < 1.5 \times {C}_{W 0} / {S}_{W} \qquad ( 4 )$$

$${C}_{W 1} \geq {C}_{W E} = {C}_{W 2} \times {C}_{E 0} / ( {C}_{W 2} + {C}_{E 0} ) \qquad ( 5 )$$

In the embodiment of G12, a difference between source radio frequency power per unit area coupled to plasma from the substrate and source radio frequency power per unit area coupled to plasma from the edge ring is reduced. In addition, in the embodiment of G12, it is possible to suppress the distribution of the electric bias supplied to the bias electrode to the edge ring. Thus, according to the embodiment of G12, the performance of independently supplying the electric bias to one of the substrate and the edge ring is improved. The electrostatic capacitance C_{WE} may be 10 (nF) or less.

[G13]

A plasma processing apparatus including:
a chamber;
a substrate support disposed in the chamber, the substrate support including a base, a dielectric portion disposed on the base, and a bias electrode, the dielectric portion including a first region configured to support a substrate placed thereon and a second region surrounding the first region and configured to support an edge ring placed thereon, and the bias electrode being disposed in the second region;
a radio frequency power source electrically coupled to the base and configured to generate source radio frequency power for plasma generation; and
a bias power source electrically coupled to the base through a first electrical path and electrically coupled to the bias electrode through a second electrical path and configured to to supply an electric bias for ion attraction to the base and the bias electrode, at least one of the first electrical path and the second electrical path including a variable impedance element,
wherein an electrostatic capacitance C_{W0} between the substrate and the base, an area S_{W} of a back surface of the substrate W, an electrostatic capacitance C_{E0} between the base and the edge ring, an area S_{E} of a back surface of the edge ring, an electrostatic capacitance C_{E1} between the bias electrode and the edge ring, an electrostatic capacitance C_{EW} between the bias electrode and the substrate, and an electrostatic capacitance C_{E2} between the bias electrode and the base satisfy the following expressions (6) and (7).

$$0.5 \times {C}_{W 0} / {S}_{W} < {C}_{E 0} / {S}_{E} < 1.5 \times {C}_{W 0} / {S}_{W} \qquad ( 6 )$$

$${C}_{E 1} \geq {C}_{E W} = {C}_{W 0} \times {C}_{E 2} / ( {C}_{W 0} + {C}_{E 2} ) \qquad ( 7 )$$

In the embodiment of G13, a difference between source radio frequency power per unit area coupled to plasma from the substrate and source radio frequency power per unit area coupled to plasma from the edge ring is reduced. In addition, in the embodiment of G13, it is possible to suppress the distribution of the electric bias supplied to the bias electrode to the wafer. Thus, according to the embodiment of G13, the performance of independently supplying the electric bias to one of the substrate and the edge ring is improved. The electrostatic capacitance C_{EW} may be 10 (nF) or less.

[G14]

The plasma processing apparatus according to any one of G1 to G13, wherein the electric bias is a bias radio frequency power or a pulse of a voltage periodically generated

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a chamber;
a substrate support disposed in the chamber, the substrate support including a base, a dielectric portion disposed on the base, a first bias electrode, and a second bias electrode, the dielectric portion including a first region configured to support a substrate placed thereon and a second region surrounding the first region and configured to support an edge ring placed thereon, the first bias electrode being disposed in the first region, and the second bias electrode being disposed in at least the second region; and
at least one bias power source configured to supply an electric bias for ion attraction to the first bias electrode and the second bias electrode,
wherein a shortest distance d_{W1} between a placement position of the substrate in the first region and the first bias electrode, a shortest distance d_{WE} between the first bias electrode and a placement position of the edge ring in the second region, a shortest distance d_{E1} between the second bias electrode and the placement position of the edge ring, and a shortest distance d_{EW} between the second bias electrode and the placement position of the substrate satisfy the following expressions (A) and (B).
$${d}_{W 1} \leq {d}_{W E} \qquad ( A )$$
$${d}_{E 1} \leq {d}_{E W} \qquad ( B )$$

2. The plasma processing apparatus according to claim 1,
wherein the plasma processing apparatus comprises a first bias power source electrically coupled to the first bias electrode and a second bias power source electrically coupled to the second bias electrode, as the at least one bias power source.

3. The plasma processing apparatus according to claim 1,
wherein the plasma processing apparatus comprises a single bias power source electrically coupled to the first bias electrode through a first electrical path and electrically coupled to the second bias electrode through a second electrical path, as the at least one bias power source, and
at least one of the first electrical path and the second electrical path includes a variable impedance element.

4. The plasma processing apparatus according to claim 1,
wherein the base includes a first base disposed below the first region and a second base disposed below the second region, and
the first base and the second base are separated from each other by an other dielectric portion disposed between the first base and the second base.

5. The plasma processing apparatus according to claim 4,
wherein the plasma processing apparatus comprises a first bias power source electrically coupled to the first bias electrode and a second bias power source electrically coupled to the second bias electrode, as the at least one bias power source.

6. The plasma processing apparatus according to claim 5, further comprising a first radio frequency power source electrically coupled to the first base and a second radio frequency power source electrically coupled to the second base, as at least one radio frequency power source configured to generate source radio frequency power for plasma generation.

7. The plasma processing apparatus according to claim 4, further comprising a single radio frequency power source electrically connected to the first base through a first electrical path and electrically coupled to the second base through a second electrical path, as at least one radio frequency power source configured to generate source radio frequency power for plasma generation,
wherein at least one of the first electrical path and the second electrical path includes a variable impedance element.

8. The plasma processing apparatus according to claim 4,
wherein the plasma processing apparatus comprises a single bias power source electrically coupled to the first bias electrode through a first electrical path and electrically coupled to the second bias electrode through a second electrical path, as the at least one bias power source,
at least one of the first electrical path and the second electrical path includes a variable impedance element,
the plasma processing apparatus further comprises a single radio frequency power source electrically connected to the first base through a third electrical path and electrically coupled to the second base through a fourth electrical path, as at least one radio frequency power source configured to generate source radio frequency power for plasma generation, and
at least one of the third electrical path and the fourth electrical path includes a variable impedance element.

9. The plasma processing apparatus according to claim 1,
wherein a part of the second bias electrode is disposed to overlap the first bias electrode as viewed in a vertical direction in the first region.

10. The plasma processing apparatus according to claim 1,
wherein the electric bias is bias radio frequency power or a pulse of a voltage periodically generated.

11. The plasma processing apparatus according to claim 1,
wherein a position of an upper surface of the second region in a height direction is lower than a position of an upper surface of the first region in the height direction, and
a position of a lower surface of the second region in the height direction is lower than a position of a lower surface of the first region in the height direction.

12. The plasma processing apparatus according to claim 1,
wherein a part of the second region is integrated with the base.

13. The plasma processing apparatus according to claim 1,
wherein the first region and the second region are joined at a boundary between the first region and the second region.

14. The plasma processing apparatus according to claim 1,
wherein the substrate support further includes an electrostatic electrode disposed in the second region, and
a distance between the first bias electrode and a lower surface of the first region in a height direction is equal to a distance between the electrostatic electrode and the lower surface of the first region in the height direction.

15. The plasma processing apparatus according to claim 1,
wherein the shortest distance d_{W1} is longer than the shortest distance d_{E1}.

16. The plasma processing apparatus according to claim 1,
wherein the shortest distance d_{WE} is longer than the shortest distance d_{EW}.
